(19) United States
(12) Patent Application Publication
(10) Pub. No.: US 2022/0098735 A1
(43) Pub. Date: Mar. 31, 2022

(54) MIXED SUBSTANTIALLY HOMOGENOUS COATINGS DEPOSITED BY ALD

(71) Applicant: Greene, Tweed Technologies, Inc., Wilmington, DE (US)

(72) Inventors: Alexandru C. Pavel, Austin, TX (US); Vasil Vorsa, Coopersburg, PA (US)

(21) Appl. No.: 17/356,444

(22) Filed: Jun. 23, 2021

Related U.S. Application Data
(60) Provisional application No. 63/044,185, filed on Jun. 25, 2020.

(51) Int. Cl. C23C 16/455; C23C 16/02; C23C 16/40

(52) U.S. Cl. CPC C23C 16/45553; C23C 16/405; C23C 16/0272

(57) ABSTRACT

Disclosed herein are methods for the deposition of a plasma resistant coating onto a substrate using an atomic layer deposition process. The process includes carrying out a an ALD deposition cycle that includes at least the steps of: providing an ALD reactant chamber with a substrate; pulsing into the chamber a first coating precursor (Coat¹Pre); pulsing into the chamber a second coating precursor (Coat²Pre), substantially immediately after the completion of the pulse of Coat¹Pre; purging the chamber; pulsing into the chamber a co-reactant precursor; and purging the chamber. At completion of a cycle, a monolayer is deposited. The monolayer is or is included in a mixed coating of substantial homogeneity. The methods may be varied, e.g., the second or third steps can be repeated multiple times (1 to 4 times or 2 to 8 times). If one desired to prepare mixed coatings or more than two components, other steps may be added, e.g., at least one additional step of pulsing an additional metal precursor into the chamber substantially immediately after the completion of the pulse of the Coat¹Pre or Coat²Pre. In such embodiments, the additional precursor(s) is not the same as Coat¹Pre or Coat²Pre. Also included within the invention are coatings made by the disclosed processes (such as those having, e.g., without limitation, the mixed composition of YₓAl_{y}O_{z}, YₓZr_{y}O_{z}, YₓO_{y}F_{z}, and YₓAl_{y}Zr_{z}O_{w}) and substrates (articles) bearing such coatings.

### CROSS REFERENCE TO RELATED APPLICATION

This application claims the benefit of priority under 35 USC 119(e) to U.S. Provisional Application Ser. No. 63/044,185, filed Jun. 25, 2020, the contents of which are incorporated herein by reference.

### BACKGROUND OF THE INVENTION

To prevent contamination of semiconductor wafers, semiconductor manufacturing equipment and flat panel display manufacturing equipment made of high purity materials with low plasma erosion properties. During manufacturing, these materials are exposed to highly corrosive gases, particularly halogen-based corrosive gases such as fluorine and chorine-based gases. Materials in the processing equipment are required to have a high resistance to erosion. To address this need, ceramics coatings such as alumina and yttria have been applied. The most frequently used method in semiconductor technology to apply these coatings is thermal spray and all its variations. However, even these materials erode over leading to lower yield and costly down time.

Thus, there is a need for coatings with improved resistance to erosion. To meet these objectives, technologists have turned to development of various atomic layer deposition (ALD) processes to aid in the deposition of plasma-resistant coatings. Advantages of ALD-formed coatings include conformal, dense, and pinhole-free film or coating that can coat complex 3D shapes and high-aspect ratio holes.

However, current ALD processes do suffer some drawbacks. For example, when depositing multiple materials by current ALD processes, the materials are typically deposited in a laminate structure with well-defined layers of individual materials. The processes disclosed here provide a new ALD-based process that allows deposition of non-laminated, homogeneous mixed films or coatings of two or more materials on a substrate, such as a chamber component.

Accordingly, the inventions described herein address a further improvement over current processes for making plasma-resistant coating

### BRIEF SUMMARY OF THE INVENTION

Disclosed herein are methods for the deposition of a plasma resistant coating onto a substrate using an atomic layer deposition process. The process includes carrying out a an ALD deposition cycle that includes at least the steps of: providing an ALD reactant chamber with a substrate; pulsing into the chamber a first coating precursor (Coat¹Pre); pulsing into the chamber a second coating precursor (Coat²Pre), substantially immediately after the completion of the pulse of Coat¹Pre; purging the chamber; pulsing into the chamber a co-reactant precursor; and purging the chamber. At completion of a cycle, a monolayer is deposited. The monolayer is or is included in a mixed coating of substantial homogeneity.

The methods may be varied, e.g., the second or third steps can be repeated multiple times (1 to 4 times or 2 to 8 times). If one desired to prepare mixed coatings or more than two components, other steps may be added, e.g., at least one additional step of pulsing an additional metal precursor into the chamber substantially immediately after the completion of the pulse of the Coat¹Pre or Coat²Pre. In such embodiments, the additional precursor(s) is not the same as Coat¹Pre or Coat²Pre.

Also included within the invention are coatings made by the disclosed processes (such as those having, e.g., without limitation, the mixed composition of YₓAl_{y}O_{z}, YₓZr_{y}O_{z}, YₓO_{y}F_{z}, and YₓAl_{y}Zr_{z}O_{w}, YₓSi_{y}O_{z}) and substrates (articles) bearing such coatings.

### BRIEF DESCRIPTION OF THE SEVERAL VIEWS OF THE DRAWINGS

The foregoing summary, as well as the following detailed description of preferred embodiments of the invention may be better understood when read in conjunction with the appended drawings. The invention is not limited to the precise arrangements and instrumentalities shown in the drawings. In the drawings:

FIG. 1 is a flowchart illustrating an overview of the process steps of an embodiment of the invention;

FIG. 2, including 2a and 2b, is a TEM cross sectional image of an YₓAl_{y}O_{z} coating on a silicon substrate prepared in accordance with an embodiment of the invention;

FIG. 3 is a cross sectional EDS line scan data of elemental aluminum, yttrium, oxygen, and silicon as a function of film position from silicon surface exhibiting homogeneous composition to the films surface;

FIG. 4 is a table listing exemplary precursors that may be used in various combinations to deposit the coating of the invention;

FIG. 5 is a TEM cross sectional image of an YₓAl_{y}O_{z} coating on a silicon substrate prepared in accordance with another embodiment of the invention where the ratio of Y/Al is about 3 to 1;

FIG. 6 is an EDS line profile of the elemental composition of the coating shown in FIG. 5;

FIG. 6A illustrates the direction in which the EDS line profile data of FIG. 6 was obtained;

FIG. 7 is an elemental map of the coating and substrate of FIG. 5 showing the distribution of silicon (where the silicon is represented by the lighter areas);

FIG. 8 is an elemental map of the coating and substrate of FIG. 5 showing the distribution of yttrium (where the yttrium is represented by the lighter areas);

FIG. 9 is an elemental map of the coating and substrate of FIG. 5 showing the distribution of aluminum (where the aluminum is represented by the lighter areas);

FIG. 10 is an elemental map of the coating and substrate of FIG. 5 showing the distribution of oxygen (where the oxygen is represented by the lighter areas);

FIG. 11 is a graph showing the data obtained from grazing incidence X-ray diffraction (GIXRD) analysis of the coating of FIG. 5;

FIG. 12 is a table presenting the data obtained from analysis of the coating of FIG. 5 via Rutherford Backscattering (RBS) analysis;

FIG. 13 is a TEM cross sectional image of an YxAlyOz coating on a silicon substrate prepared in accordance with another embodiment of the invention where the ratio of Y/Al is 2 to 1;

FIG. 14 is an EDS line profile of the elemental composition of the coating shown in FIG. 14;

FIG. 14A illustrates the direction in which the EDS line profile data of FIG. 14 was obtained;

FIG. 15 is an elemental map of the coating and substrate of FIG. 13 showing the distribution of silicon (where the silicon is represented by the lighter areas);

FIG. 16 is an elemental map of the coating and substrate of FIG. 13 showing the distribution of yttrium (where the yttrium is represented by the lighter areas);

FIG. 17 is an elemental map of the coating and substrate of FIG. 13 showing the distribution of aluminum (where the aluminum is represented by the lighter areas);

FIG. 18 is an elemental map of the coating and substrate of FIG. 13 showing the distribution of oxygen (where the oxygen is represented by the lighter areas);

FIG. 19 is a graph showing the data obtained from grazing incidence X-ray diffraction (GIXRD) analysis of the coating of FIG. 13;

FIG. 20 is a table presenting the data obtained from analysis of the coating of FIG. 14 via Rutherford Backscattering (RBS) analysis;

FIG. 21 is a TEM cross sectional image of a thick YxAlyOz coating on a silicon substrate prepared in accordance with another embodiment of the invention where the ratio of Y/Al is 50 to 50;

FIG. 22 is an EDS line profile of the elemental composition of the coating shown in FIG. 23;

FIG. 22A illustrates the direction in which the EDS line profile data of FIG. 22 was obtained;

FIG. 23 is an elemental map of the coating and substrate of FIG. 21 showing the distribution of silicon (where the silicon is represented by the lighter areas);

FIG. 24 is an elemental map of the coating and substrate of FIG. 21 showing the distribution of yttrium (where the yttrium is represented by the lighter areas);

FIG. 25 is an elemental map of the coating and substrate of FIG. 21 showing the distribution of aluminum (where the aluminum is represented by the lighter areas);

FIG. 26 is an elemental map of the coating and substrate of FIG. 21 showing the distribution of oxygen (where the oxygen is represented by the lighter areas); and

FIG. 27 is a schematic showing an embodiment of the process of the invention as described herein.

### DETAILED DESCRIPTION OF THE INVENTION

The invention as described herein includes atomic layer deposition-based (ALD-based) methods of depositing non-laminate homogeneous coatings of two or more metal oxides, fluorides or nitrides (“mixed coatings”), the mixed coating itself and substrates bearing the mixed coatings.

Conventional ALD processes can be used to deposit multiple materials; however, such processes result in films or coatings having laminate structures with well-defined layers of individual materials. Theoretically, it is believed that a more uniform distribution of the selected multiple materials may result if a simultaneous deposition of the materials was used. However, many current ALD reactors do not permit this option. The processes described herein have been developed that permit use of a conventional ALD reactor to achieve deposition of non-laminated, homogeneous mixed coatings of two or more materials, i.e., one can prepare coatings in which two or more metal cations are present within the same monolayer.

In particular, the methods of the invention enable one to deposit metal oxides that have two or more metal cations within a single monolayer and ternary, quaternary or greater oxides of fixed stoichiometry while maintaining control over the structure and properties of the monolayer by immediately consecutive pulsing of the components' precursors in the ALD process.

In the practice of the inventive methods, one can vary the atomic ratio between or among the two or more metal cations to prepare structures specifically tailored to the end application in which the coatings will be used. Moreover, since the ALD method of the invention may be used to deposit materials with ternary, quaternary or greater structures, ALD deposition of garnet and perovskites materials becomes less of a technical challenge.

The processes, coatings and coating-bearing substrates of the invention in their various embodiments are useful to prepare and/or to coat substrates that form components useful in a variety of industries, especially those where components may be exposed to high temperatures, and/or corrosive chemicals. For example, the coatings of the invention may be used on components that are found in equipment/machines/devices used in aerospace, pharmaceutical production, food processing, oil field applications, military and/or maritime applications, industrial manufacturing, and scientific and/or diagnostic instrumentation.

The practice of the process includes a substrate to which the coating is applied. The substrate may be any material useful for the desired end applications. In some embodiments, one may prefer that the substrate is a non-ferrous metal, a non-ferrous metal alloy, a ferrous metal or a ferrous metal alloy. Suitable materials may include substrates of titanium, titanium alloys, nickel alloys, aluminum, nickel, ceramics, aluminum alloys, steels, stainless steel, carbon steel, alloy steel, copper, copper alloys, lead, lead alloys, ceramics, quartz, a glass, a polymer, such as a high performance polymer, and a fiberglass. The substrate may also combine materials, that is, a portion may be, for example, made of aluminum and an adjacent portion made of copper.

The coated substrate may make up or be part of a variety of components, such as, for example, components that are planar in nature or have a 3D geometry. For example, the component may be a chamber component, like a shower head, a chamber wall, a nozzle a plasma generation unit, a diffuser, a gas line interior, a chamber orifice, and the like.

As noted, the invention may be used in any sector of industry. However, a development focus of the invention included substrates in the semiconductor manufacture arena. In semiconductor manufacturing, the processes used expose semiconductor process chamber components to high temperatures, high energy plasma, a mixture of corrosive gases, and/or high-level stressors. Coating semiconductor process chamber components with protective coatings is an effective way to reduce defects and extend their use lifetime. As used herein, the term “chamber component” refers to a component used in a semiconductor manufacturing process chamber, such as, for example, a plasma etcher or plasma etch reactor, and a plasma cleaner. Without limitation, examples of these components include substrate support assemblies, wafer boats, electrostatic chucks, rings, chamber walls, chamber bases, gas distribution plates, gas lines, gas nozzles, portals, showerheads, lids, liners, shields, escutcheons, plasma screens, flow equalizers, cooling bases, fasteners, ports, etc.

Once the substrate is selected it is placed in the reaction chamber of an ALD tool. Any ALD tool may be used and they are commonly available, such as, for example, those available from Picosun (P-series and R-series ALD systems); Beneq Oy (TFS-series or P-series) Oxford Instruments (FlexAl and OpalAl ALD systems); and/or Veeco Instruments (Savannah, Fiji, and Phoenix ALD systems).

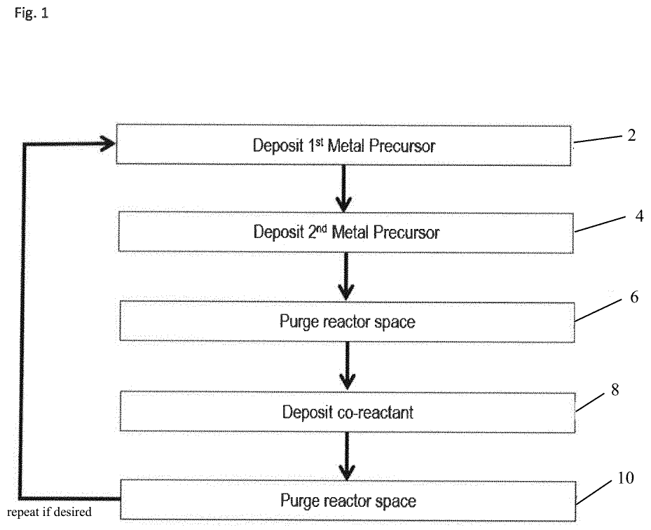

The method described herein is illustrated schematically in the flowchart of FIG. 1 and may be adapted as described in more detail below to produce mixed coatings of two, three, four, five, six or more materials, e.g., multiple different oxides, multiple different fluorides, multiple different nitrides or a combination of one or more oxides, one or more fluorides and/or one or more nitrides.

With reference to FIG. 1 and using the known protocols associated with selected ALD tool, the coating process begins with a first pulse 2 into the chamber of a first coating precursor (“Coat¹Pre”), followed substantially immediately by a pulse 4 of a second coating precursor (“Coat²Pre”) into the chamber. By “substantially immediately” it is meant that the subsequent pulse is initiated within 0.0 to 1.0 seconds after the completion of the previous pulse. The pulses are applied consecutively; no purge of the reaction chamber is carried out between the pulses. Coat¹Pre and Coat²Pre are not identical to one another, so the resultant coating includes at least two components. The duration of the pulse(s) will vary but is generally between about 0.01 to about 120 seconds or about 0.01 to about 10 seconds. In some instances, if the process is carried out under a lower pressure, the pulses may be longer.

In alternative embodiments, one may wish to prepare a mixed coating more than two materials. In such instance, a pulse of a third coating precursor (“Coat³Pre”), a pulse of a fourth coating precursor (“Coat⁴Pre”), a pulse of a fifth coating precursor (“Coat⁵Pre”) fifth pulse, etc., may be introduced into the ALD reaction chamber sequentially and each substantially immediately after the previous pulse. Again, the pulses are applied consecutively; no purge of the reaction chamber is carried out in between the pulses. The precursors are not identical to one another, enabling the preparation of a 3-, 4-, 5-, etc., component coating.

After all desired coating precursors have been added to the reaction chamber, the chamber is purged, see FIG. 1 at 6, usually using nitrogen (N₂) (for about 0.01 to about 120 seconds). In various embodiments, the purge step(s) can be accomplished using argon, or any other inert gas(es) in place of or mixed with nitrogen.

It is noted that the dose and purge times given above in ranges are merely illustrative. It is well within the skillset of a person of ordinary skill in the art to determine dose time and purges times for an ALD process. As in known in the art, ALD reactions are self-limiting. The ALD reaction must have optimized dosing concentrations and times plus optimized purge times for each of the precursors.

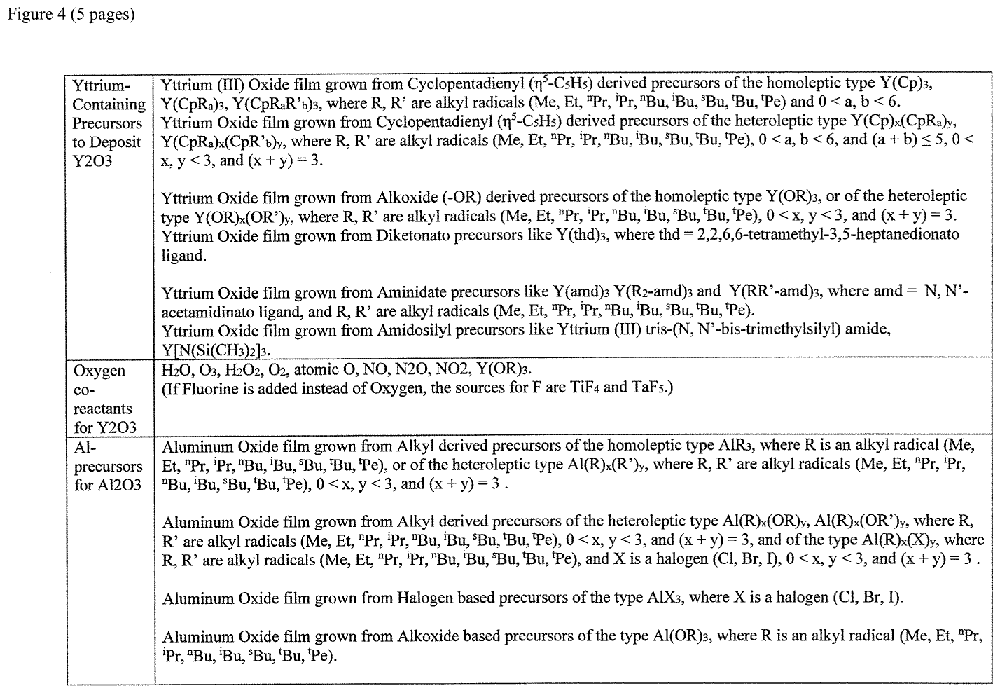

Following the purge of the coating precursors, a pulse of co-reactant precursor 8 is added. Such co-reactants include oxidizer precursors (to grow oxides), fluoride precursors (to grow fluorides), and/or nitride precursors (to grow nitrides). Specific examples include, without limitation, water, an H₂O₂, O₂, O₂ plasma, NH₄F O₃, H₂O₂, N₂O, NO₂, NO and mixtures of the same (oxidizer precursors), hydrogen fluoride (“HF”), HF-pyridine, (fluoride precursors), tetrakis(dimethylamino)titanium (TDMAT), NH₃, H₂N-NH₂ (nitride precursor). Other examples are shown the table of FIG. 4. In an embodiment where the process is repeated two times or more, it may be preferred that the co-reactant precursor is the same for each repetition.

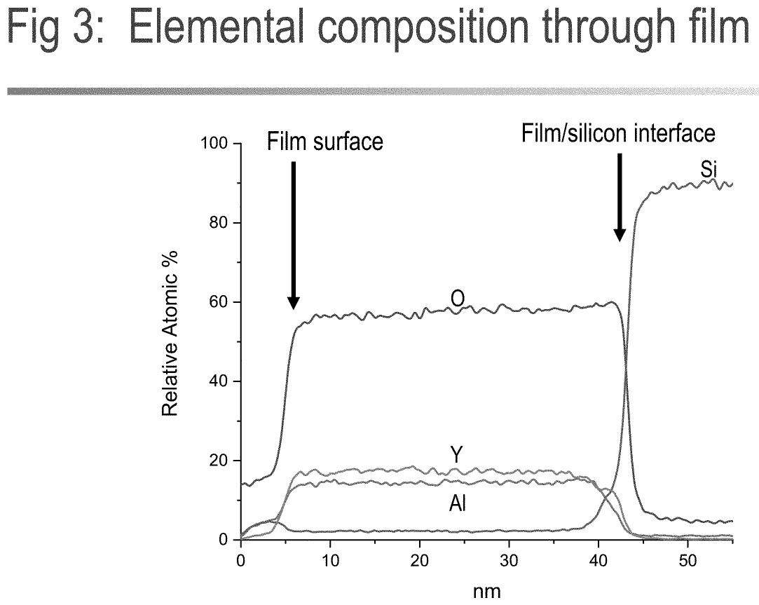

The reaction chamber is then purged 10 again in a manner as described above. This process, described by the process blocks 2, 4, 6, 8, 10 in FIG. 1 results in one mixed monolayer that is substantially homogenous and/or can be characterized as exhibiting substantial homogeneity. As used herein “homogenous” and its grammatical counterparts refer to the fact that the coating or monolayer so-described is free of well-defined or differentiated layers when viewed via TEM in a 5 nm section and/or no area of the coating is a single component above the molecular level. See, for example, the micrograph of FIG. 3. The process can be repeated as many times as desired, e.g., about 2 times to about 20,000 times or about 100 times to about 100,000 times.

In an embodiment, the substrate is pretreated by cleaning or heating before beginning the process. Additionally, one may wish to deposit a preliminary or primer layer on the substrate before initiating the above-described process. The primer layer may be a metal oxide layer, for example, aluminum oxide. It may be formed by any process including, for example, ALD, anodization, thermal spray, sputtering, vapor deposition and evaporation techniques.

Also, one may subject the coating to an annealing step as is known or developed in the art. In some embodiments, the deposited mixed homogeneous film may be annealed in order to transform the film from amorphous to a crystalline phase. For example, it may be desired to transform the as deposited, amorphous YAlO₃ film into an yttrium aluminum oxide perovskite or, in a different formulation, convert the amorphous Y₃Al₅O₁₂ into a crystalline Y₃Al₅O₁₂ garnet. Amorphous YxSiyOz can be thus converted into various crystalline phases of yttrium silicates with the same approximate chemical formula. Annealing may also take place in an oxygen atmosphere with the motivation to reduce oxygen vacancies. Another reason for post-deposition annealing is to dry the film of residual excess water that may be stored within the structure of the coating.

The coating precursors selected for use in the preparation of the coating will vary depending on what components on wishes to have mixed in the monolayer(s). Any known or developed for use in the ALD arts may be used. Examples include without limitation, those in FIG. 4. In various embodiments, one may prefer to use metal¹ precursor, such as for example, those having one of a lanthanide series element, yttrium, aluminum, silicon, cerium, zirconium, titanium, hafnium, scandium, and then use a metal² precursor from the same set of choices as for the metal¹ precursor, or extended to choices of transitional metals and actinides. Illustratively, any one or more of the coating precursors may be one or more of trimethyl aluminum (“TMA”), tris(2,2,6,6-tetramethyl-3,5-heptanedionato)yttrium(III), TiF4, diethylaluminum ethoxide, tris(ethylmethylamido)aluminum, aluminum sec-butoxide, aluminum tribromide, aluminum trichloride, triethylaluminum, triisobutylaluminum, trimethylaluminum, or tris(diethylamido)aluminum, zirconium (IV) bromide, zirconium (IV) chloride, zirconium (IV) tert-butoxide, tetrakis(diethylamido)zirconium (IV), tetrakis(dimethylamido)zirconium (IV), and tetrakis(ethylmethylamido)zirconium (IV).

In an embodiment of the method, the coating includes at least one monolayer that is a mixed composition of YₓAl_{y}O_{z}, or YₓAl_{y}Zr_{z}O_{w}. In such embodiment, one may use trimethyl aluminum as one of the precursors from which the monolayer is grown.

The invention also encompasses the coatings and films prepared by the methods, and substrates, articles or components that have surfaces that are coated or bear the coating, either wholly or in part. The multi-component coating prepared as disclosed herein may be a coating having multiple different oxides, multiple different fluorides, or a combination of one or more oxides and one or more fluorides.

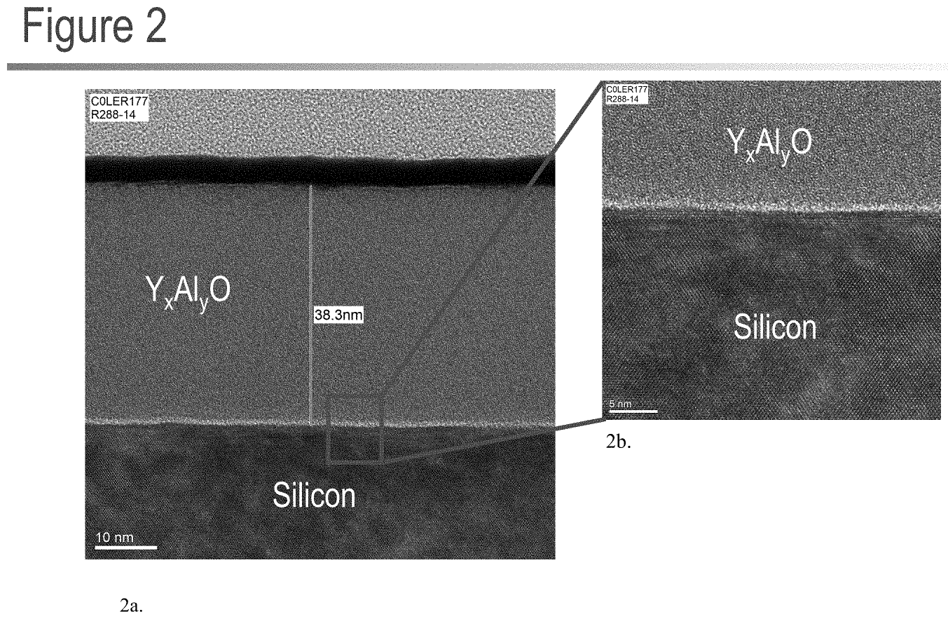

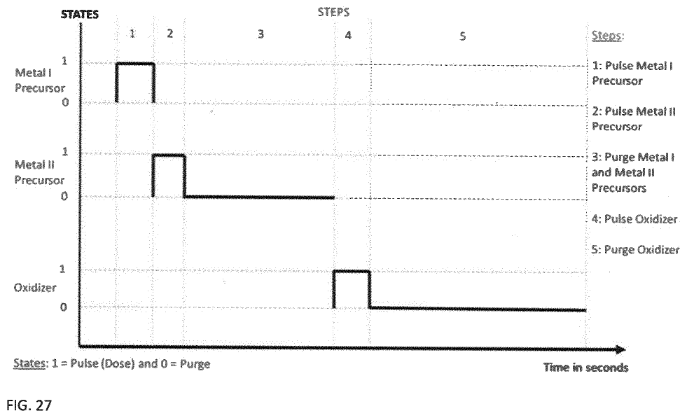

FIG. 2 (including 2a and 2b) shows TEM cross sectional images of a YₓAl_{y}O_{z} coating on a silicon substrate prepared in accordance with an embodiment of the invention. In this embodiment, the film was deposited by pulsing yttrium precursor 2 times followed immediately by pulsing aluminum precursor 3 times followed by a purge, followed by an oxide pulse followed by purge and repeating for 96 super-cycles, total is 384 cycles. 2b shows a “zoom” of the image at the film/substrate interface. FIG. 3 is a cross sectional EDS line scan data of elemental aluminum, yttrium, oxygen, and silicon as a function of film position from silicon surface exhibiting homogeneous composition to the films surface in the film of an embodiment. FIG. 27 illustrates an embodiment of the process of the invention schematically showing the presence/absence of the reactants in the chamber over time in seconds as the process progresses.

Specifically, the coating was deposited by pulsing an yttrium precursor one time, followed substantially immediately by the pulsing of an aluminum precursor one time, followed by a purge, then an oxidative pulse and a second purge. This was retreated for 384 super cycles.

In various embodiments, the resulting mixed coating includes at least one monolayer having a composition that is one of YₓAl_{y}O_{z}, YₓZr_{y}O_{z}, YₓO_{y}F_{z}, YₓAl_{y}Zr_{z}O_{w}, and YₓSi_{y}O_{z}.

In additional or alternative embodiments, the mixed coating may contain at least two materials selected from aluminum oxide, yttrium oxide, a lanthanide series element oxide or fluoride, zirconium oxide, hafnium oxide, binary, ternary or quaternary metal oxides containing at least one rare earth metal, Y₂O₃, La₂O₃, HfO₂, Ta₂O₅, Er₂O3, ZrO₂, Y₃Al₅O₁₂ (YAG), Er₃Al₅O₁₃ (EAG), Y₄Al₂O₉ (YAM), YAlO₃ (YAP), Er₄Al₂O₉ (EAM), ErAlO₃ (EAP), fluorides of yttrium, zirconium, hafnium and mixtures of the same.

The mixed coating may be any thickness; desired thicknesses will vary depending on the end application in which the coating or coated substrate (article) is to be used. The thickness of the coating can be varied by increasing or decreasing the number of monolayers deposited to form the coating, e.g., about 1 to about 100,000, about 1 to about 5000, and about 1 to about 1000.

As an example, the coating may have a thickness of about 10 to about 10,000 nanometers of about 30 to about 100 nanometers and/or of about 40 to about 60 nanometers. In an embodiment, the mixed coating comprises a structure that is amorphous.

### Example 1—Preparation of An Amorphous YₓAl_{y}O_{z}, Plasma Etch-Resistant Coating

A 39.5 nm YₓAl_{y}O_{z} plasma etch-resistant coating was deposited on the surface of a silicon substrate shown in FIG. 2 in a standard cross-flow type ALD reactor. A 200 mm silicon wafer substrate was placed in the middle slot of a wafer holder placed inside the ALD reactor. The reactor was then pumped down by a vacuum pump while purging with nitrogen to a pressure of 0.3 hPa. The temperature of the reaction chamber was set to 250° C. The flow rate through the reactor line was set at 300 sccm. The flow rates through all the cursor delivery lines were all set at 150 sccm.

YₓAl_{y}O_{z} was deposited using tris-(methylcyclopentadienyl) yttrium precursor, trimethyl aluminum (TMA), and water as the co-reactant. The yttrium precursor vessel temperature was set at 145° C., while the TMA and the water vessel temperatures were both set at 22° C.

The recipe starts by a short (8×) half-cycle of water pulsing (0.2 seconds)/purging (24.0 seconds) for the hydroxylation of the Si wafer surface. The pulsing/purging scheme for the deposition of YₓAl_{y}O_{z}, monolayers was structured in the following sequence: a 0.3 seconds yttrium precursor vapor pulse followed by a 0.3 seconds aluminum precursor vapor pulse, and then purging of the 2 different metal precursors through a nitrogen purge step of 18.0 seconds. This was followed by a 0.2 second water vapor pulse and by a second nitrogen purge step of 18 seconds. This sequence of steps was repeated for 384 cycles to build up a 46 nm thick layer of Y₂O₃. The recipe ends with a short (4×) half-cycle of water pulsing (0.2 seconds) / purging (24.0 seconds) for the hydroxylation of the ternary oxide coating surface.

The resulted coating was amorphous in structure due to the aluminum oxide contribution and was close to a targeted 1/1 atomic ratio between the two metal cations. FIG. 3 shows a cross sectional EDS line scan data of elemental aluminum, yttrium, oxygen, and silicon as a function of each's position within the film exhibiting a homogeneous composition to the films surface.

### Example 2—Preparation of a Target 3:1 Y/Al Ratio Plasma Etch-Resistant Coating of YₓAl_{y}O_{z} on a Silicon Substrate

A YₓAl_{y}O_{z} plasma etch-resistant coating was deposited on the surface of a silicon substrate in a standard cross-flow type ALD reactor. A 50 nm silicon wafer substrate was placed in the middle slot of a wafer holder placed inside the ALD reactor. The reactor was then pumped down by a vacuum pump while purging with nitrogen to a pressure of 0.3 hPa. The temperature of the reaction chamber was set to 250° C. The flow rates through the reactor line and the precursor delivery lines were set as in Example 1.

YₓAl_{y}O_{z} was deposited using tris-(methylcyclopentadienyl) yttrium precursor, trimethyl aluminum (TMA), and water as the co-reactant. The yttrium precursor vessel temperature was set at 145° C., while the TMA and the water vessel temperatures were both set at 22° C.

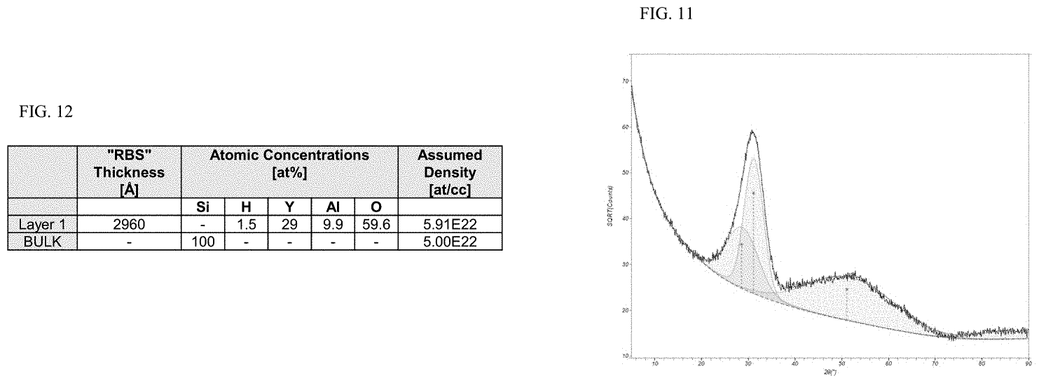

The process initiates by a (8×) half-cycle of water pulsing (0.2 seconds)/purging (24.0 seconds) for the hydroxylation of the silicon substrate surface. Subsequently, pulsing/purging scheme was of the following sequence: a 1.4 seconds yttrium precursor vapor pulse followed by a 0.3 seconds aluminum precursor vapor pulse, and then purging of the 2 different metal precursors through a nitrogen purge step of 18.0 seconds. This was followed by a 0.2 second water vapor pulse and by a second nitrogen purge step of 18 seconds. This sequence of steps was repeated for 2,184 cycles to build up the layer. The coating prepared had a thickness of about 253 nm and was amorphous in structure, as confirmed by the data obtained via grazing incidence X-ray diffraction (GIXRD) analysis, shown in FIG. 11.

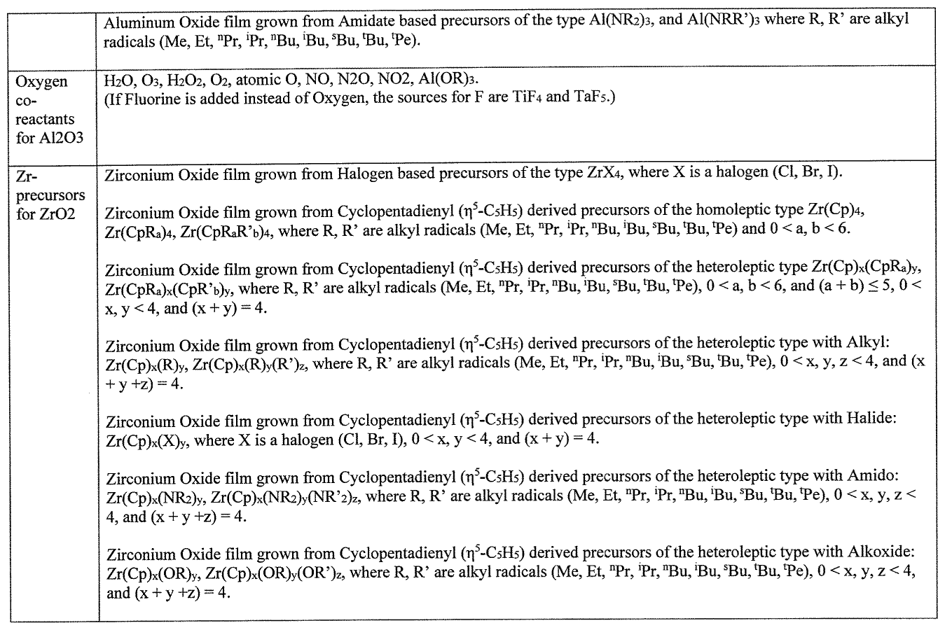

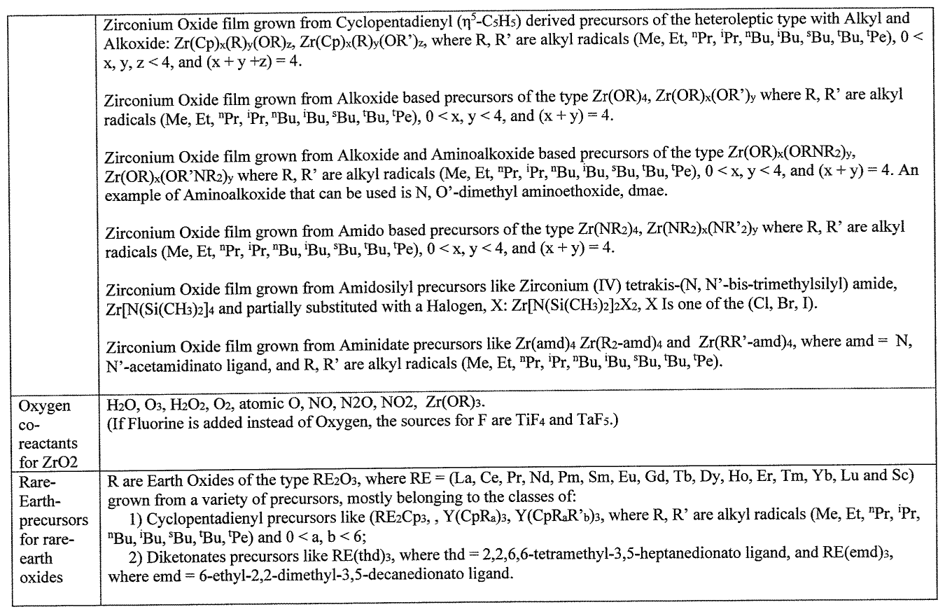

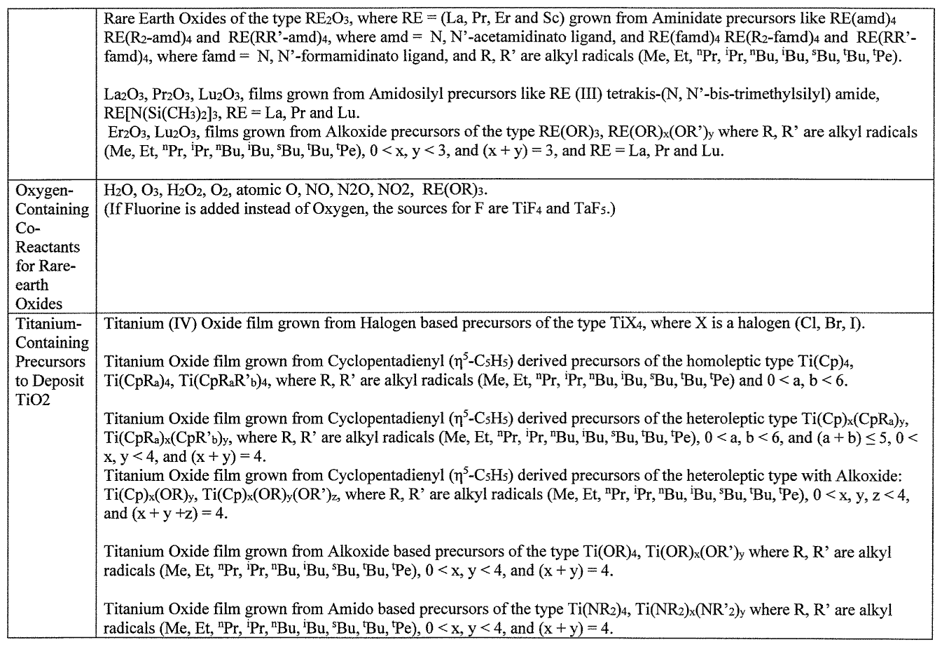

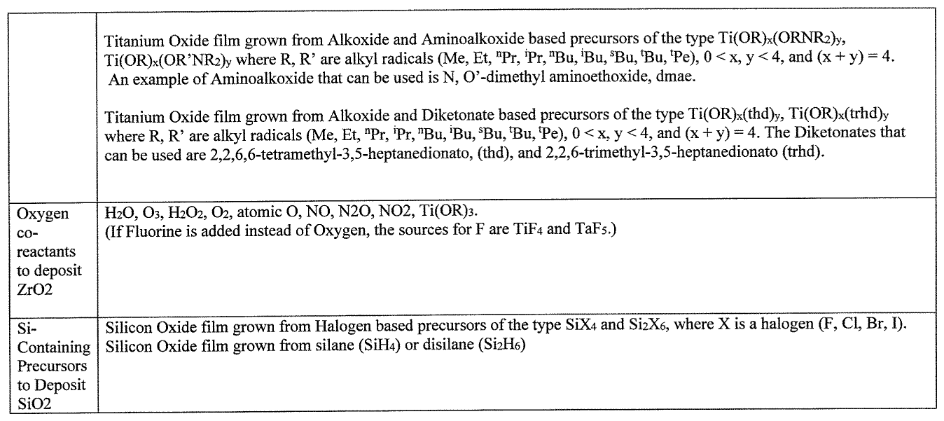

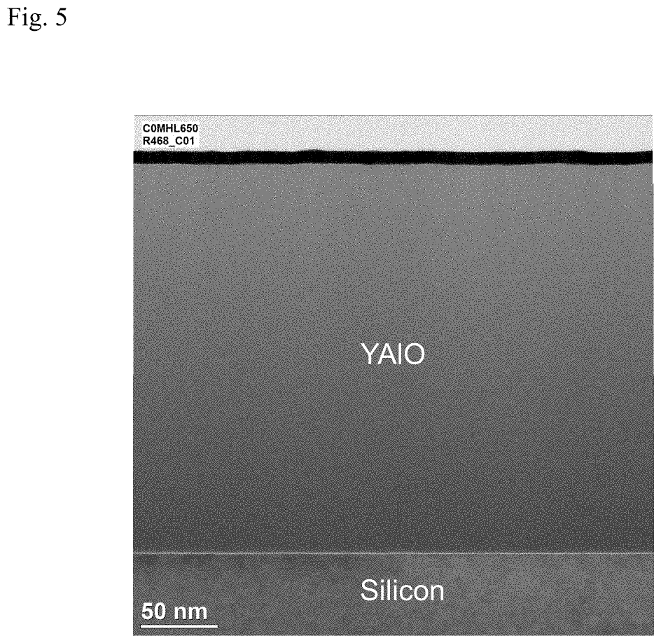

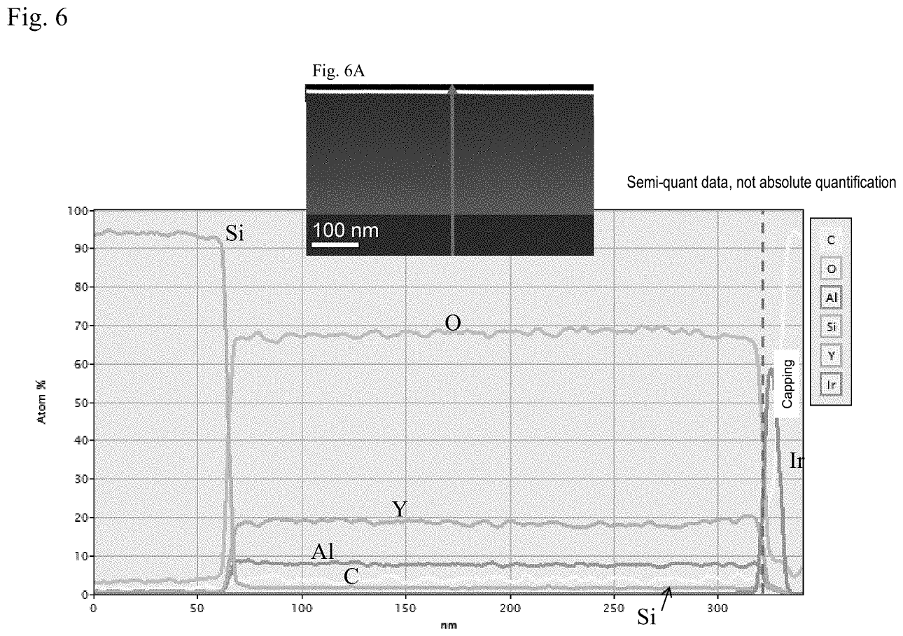

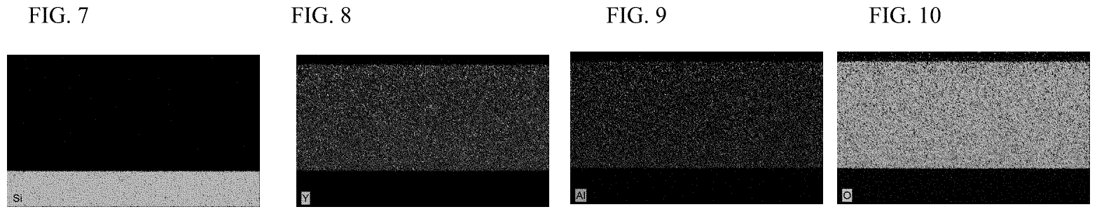

FIG. 5 shows a TEM of the resultant coating in cross section. FIG. 6 shows an EDS line profile of the elemental composition of the coating, with FIG. 6A illustrating the direction in which the EDS line profile data was obtained. FIGS. 7 to 10 are EDS elemental maps of the coating: FIG. 7 identifies the distribution of elemental silicon (substrate only). FIG. 8 identifies the distribution within the coating of yttrium. FIG. 9 identifies the distribution within the coating of aluminum. FIG. 10 identifies the distribution within the coating of oxygen.

The Rutherford Backscattering (RBS) data shown in the table of FIG. 12 confirms that the coating contains Y and Al in a ratio of 2.93:1.

### Example 3—Preparation of a Target 2:1 Y/Al Ratio Plasma Etch-Resistant Coating of YₓAl_{y}O_{z} on a Silicon Substrate

A YₓAl_{y}O_{z} plasma etch-resistant coating was deposited on the surface of a silicon substrate in a standard cross-flow type ALD reactor. A 50 nm silicon wafer substrate was placed in the middle slot of a wafer holder placed inside the ALD reactor. The reactor was then pumped down by a vacuum pump while purging with nitrogen to a pressure of 0.3 hPa. The temperature of the reaction chamber was set to 250° C. The flow rates through the reactor line and the precursor delivery lines were set as in Example 1.

YₓAl_{y}O_{z} was deposited using tris-(methylcyclopentadienyl) yttrium precursor, trimethyl aluminum (TMA), and water as the co-reactant. The yttrium precursor vessel temperature was set at 145° C., while the TMA and the water vessel temperatures were both set at 22° C.

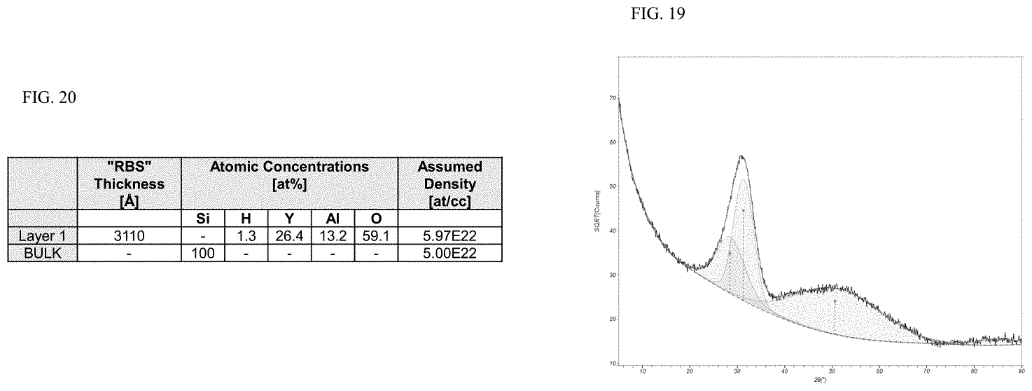

The process initiates by a (8×) half-cycle of water pulsing (0.2 seconds)/purging (24.0 seconds) for the hydroxylation of the silicon substrate surface. Subsequently, pulsing/purging scheme was of the following sequence: a 0.8 second yttrium precursor vapor pulse followed by a 0.3 seconds aluminum precursor vapor pulse, and then purging of the 2 different metal precursors through a nitrogen purge step of 18.0 seconds. This was followed by a 0.3 second water vapor pulse and by a second nitrogen purge step of 18 seconds. This sequence of steps was repeated for 2,432 cycles to build up the layer. The coating prepared had a thickness of about 257 nm and was amorphous in structure, as confirmed by the data obtained via grazing incidence X-ray diffraction (GIXRD) analysis, shown in FIG. 19.

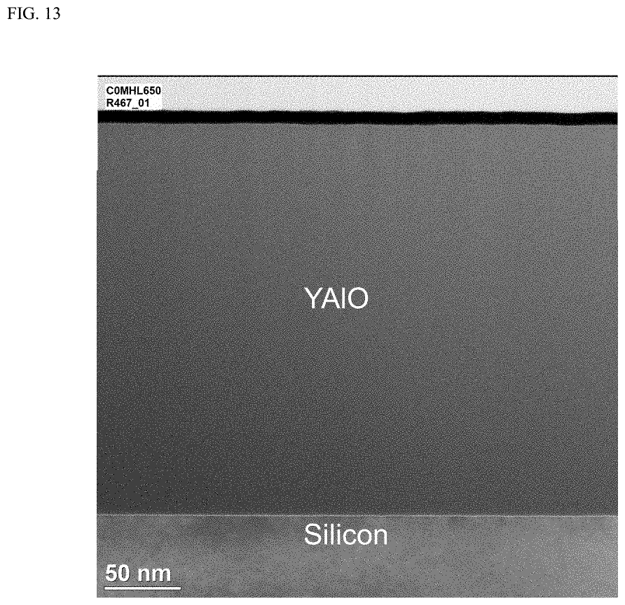

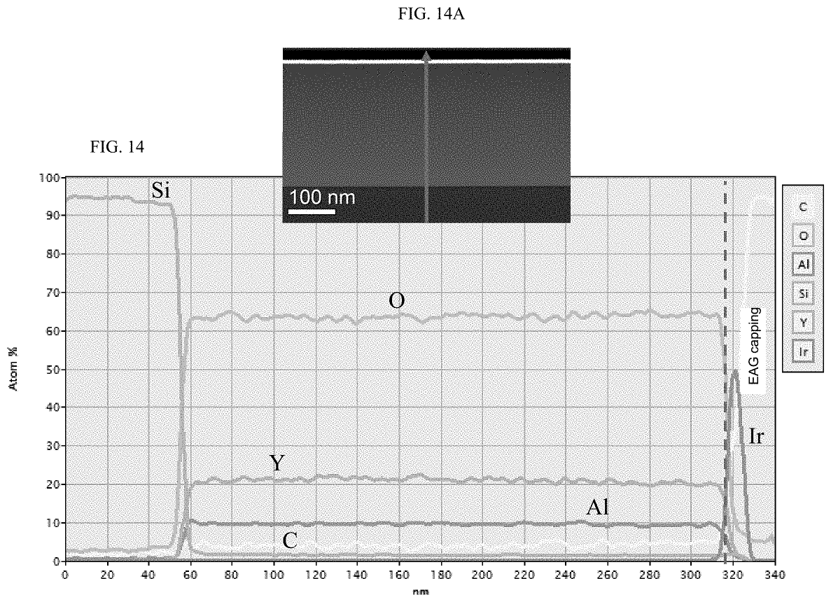

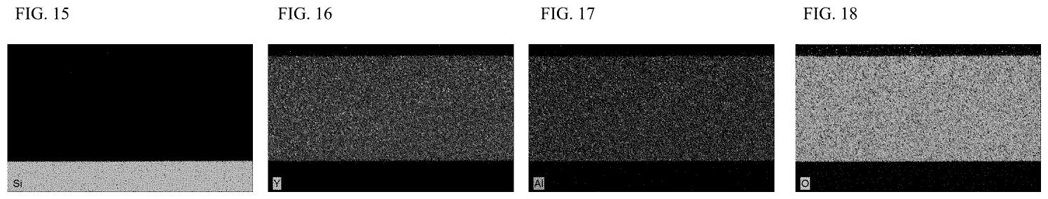

FIG. 13 shows a TEM of the resultant coating in cross section. FIG. 14 shows an EDS line profile of the elemental composition of the coating, with FIG. 14A illustrating the direction in which the EDS line profile data was obtained. FIGS. 15 to 18 are EDS elemental maps of the coating: FIG. 15 identifies the distribution of elemental silicon (substrate only). FIG. 16 identifies the distribution within the coating of yttrium. FIG. 17 identifies the distribution within the coating of aluminum. FIG. 18 identifies the distribution within the coating of oxygen.

The Rutherford Backscattering (RBS) data shown in the table of FIG. 24 confirms that the coating contains Y and Al in a ratio of 2:1.

### Example 4—Preparation of a Target 50:50 Y/Al Ratio Plasma Etch-Resistant Coating of YₓAl_{y}O_{z} on a Silicon Substrate

A YₓAl_{y}O_{z} plasma etch-resistant coating was deposited on the surface of a silicon substrate in a standard cross-flow type ALD reactor. A 100 nm silicon wafer substrate was placed in the middle slot of a wafer holder placed inside the ALD reactor. The reactor was then pumped down by a vacuum pump while purging with nitrogen to a pressure of 0.3 hPa. The temperature of the reaction chamber was set to 250° C. The flow rates through the reactor line and the precursor delivery lines were set as in Example 1.

YₓAl_{y}O_{z} was deposited using tris-(methylcyclopentadienyl) yttrium precursor, trimethyl aluminum (TMA), and water as the co-reactant. The yttrium precursor vessel temperature was set at 145° C., while the TMA and the water vessel temperatures were both set at 22° C.

The process initiates by a (8×) half-cycle of water pulsing (0.2 seconds)/purging (24.0 seconds) for the hydroxylation of the silicon substrate surface. Subsequently, pulsing/purging scheme was of the following sequence: a 0.2 second yttrium precursor vapor pulse followed by a 0.3 second aluminum precursor vapor pulse, and then purging of the 2 different metal precursors through a nitrogen purge step of 18.0 seconds. This was followed by a 0.2 second water vapor pulse and by a second nitrogen purge step of 18 seconds. This sequence of steps was repeated for 8000 cycles to build up the layer. The coating prepared had a thickness of about 813 nm and was amorphous in structure, as confirmed by the data obtained via grazing incidence X-ray diffraction (GIXRD) analysis.

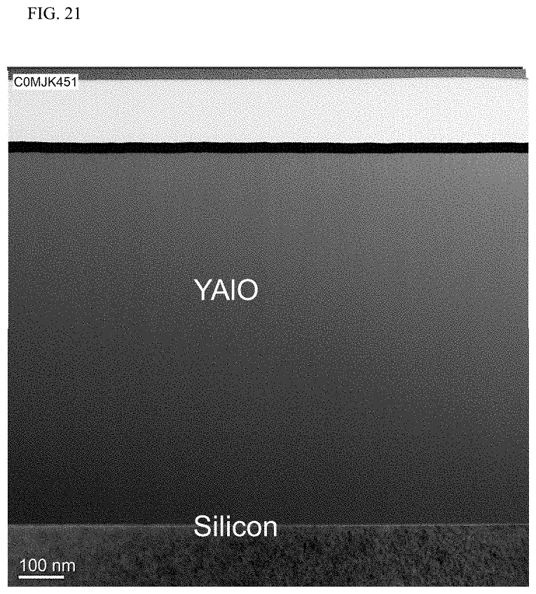

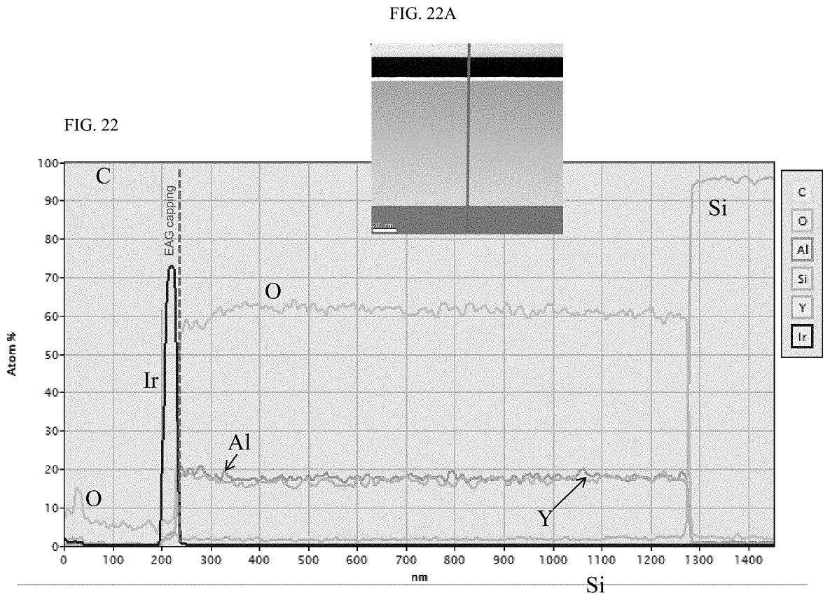

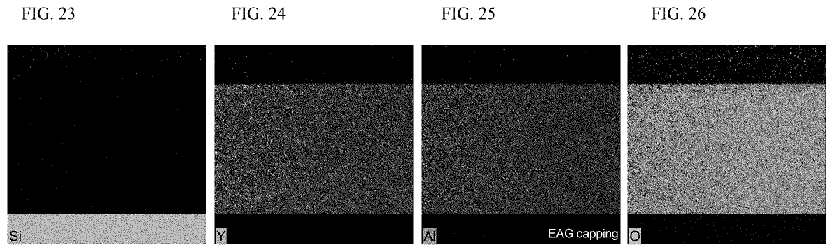

FIG. 21 shows a TEM of the resultant coating in cross section. FIG. 22 shows an EDS line profile of the elemental composition of the coating, with FIG. 22A illustrating the direction in which the EDS line profile data was obtained. FIGS. 23 to 26 are EDS elemental maps of the coating: FIG. 23 identifies the distribution of elemental silicon (substrate only). FIG. 24 identifies the distribution within the coating of yttrium. FIG. 25 identifies the distribution within the coating of aluminum. FIG. 26 identifies the distribution within the coating of oxygen.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1. A method for the deposition of a plasma resistant coating onto a substrate using an atomic layer deposition process that comprises conducting an ALD deposition cycle that comprises:
a. Providing an ALD reactant chamber with a substrate;
b. Pulsing into the chamber a first coating precursor (Coat¹Pre);
c. Pulsing into the chamber a second coating precursor (Coat²Pre), substantially immediately after the completion of the pulse of Coat¹Pre;
d. Purging the chamber;
e. Pulsing into the chamber a co-reactant precursor; and
f. Purging the chamber,
to deposit a monolayer, wherein the coating thereby formed is a mixed coating of substantial homogeneity.

2. The method of claim 1 wherein step (b) is repeated 1 to 16 times.

3. The method of claim 1 wherein step (c) is repeated 1 to 8 times.

4. The method of claim 1 wherein the mixed coating comprises at least one monolayer having a composition selected from YₓAl_{y}O_{z}, YₓZr_{y}O_{z}, YₓO_{y}F_{z}, YxSiyOz, and YₓAl_{y}Zr_{z}O_{w}.

5. The method of claim 1 further comprising at least one additional step of pulsing an additional metal precursor into the chamber substantially immediately after the completion of the pulse of Coat¹Pre: or Coat²Pre, wherein the additional precursor is not the same as Coat¹Pre or Coat²Pre.

6. The method of claim 1 further comprising at an additional step after step (c) comprising:
c-1. Pulsing into the chamber a third coating precursor (Coat³Pre), substantially immediately after the completion of the pulse of Coat²Pre.

7. The method of claim 3 further comprising an additional step after step (c-1) comprising:
c-2. Pulsing into the chamber a fourth coating precursor (Coat⁴Pre), substantially immediately after the completion of the pulse of Coat³Pre.

8. The method of claims 1 wherein the co-reactant precursor is an oxidizer precursor (OxPre).

9. The method of claim 8 wherein the OxPre is selected from water, hydrogen peroxide, ozone, O₂, O₂-plasma and/or mixtures thereof.

10. The method of claim 1 wherein the co-reactant precursor is independently selected from a fluoride precursor and a nitride precursor.

11. The method of claim 1 wherein the precursor is a metal precursor and a metal of the metal precursor is independently selected from a lanthanide series element, yttrium, scandium, cerium, aluminum, silicon, zirconium, titanium, and hafnium.

12. The method of claim 1 wherein the precursor is a metal precursor and a metal of the metal precursor is independently selected from aluminum, a Rare Earth element, tantalum, lanthanum, or erbium, and mixtures thereof.

13. The method of claim 1 wherein any one or more of the coating precursors is independently selected from precursors comprising trimethyl aluminum (“TMA”), tris(2,2,6,6-tetramethyl-3,5-heptanedionato)yttrium(III), TiF₄, diethylaluminum ethoxide, tris(ethylmethylamido)aluminum, aluminum sec-butoxide, aluminum tribromide, aluminum trichloride, triethylaluminum, triisobutylaluminum, trimethylaluminum, or tris(diethylamido)aluminum, zirconium (IV) bromide, zirconium (IV) chloride, zirconium (IV) tert-butoxide, tetrakis(diethylamido)zirconium (IV), tetrakis(dimetlaylamido)zirconium (IV), and tetrakis(ethylmethylamido)zirconium (IV).

14. The method of claim 1 wherein coating comprises a monolayer having a composition selected from YₓAl_{y}O_{z}, and YₓAl_{y}Zr_{z}O_{w}, YxZryOz and/or Yttria-stabilized Zirconia (YSZ) and at least one of the precursors from which the coating is grown is trimethyl aluminum

15. The method of claim 1 wherein the mixed coating formed comprises at least two materials selected from aluminum oxide, yttrium oxide, a lanthanide series element oxide or fluoride, zirconium oxide, Rare Earth Oxides, binary, ternary or quaternary metal oxides containing at least one rare earth metal, Y₂O₃, La₂O₃, HfO₂, Ta₂O₅, Er₂O₃, ZrO₂, Y₃Al₅O₁₂ (YAG), Er₃Al₅O₁₃ (EAG), Y₄Al₂O₉ (YAM), YAlO₃ (YAP), Er₄Al₂O₉ (EAM), ErAlO₃ (EAP), fluorides of yttrium, zirconium, hafnium and mixtures of the same.

16. The method of claim 1, wherein the substrate comprises a material selected from a non-ferrous metal, a non-ferrous metal alloy, a ferrous metal, and a ferrous metal alloy.

17. The method of claim 1, wherein the substrate comprises a material selected from titanium, aluminum, nickel, zinc, aluminum alloys, steels, stainless steel, carbon steel, alloy steel, copper, copper alloys, nickel alloys, lead, and lead alloys.

18. The method of claim 1 wherein the substrate is a chamber component.

19. The method of claim 1 wherein the substrate is selected from a shower head, a chamber wall, a nozzle a plasma generation unit, a diffuser, a gas line interior, and a chamber orifice.

20. The method of claim 1 wherein the substrate is selected from a planar member and a 3D shape, a 3D shape with high aspect ratio features and a 3D shape with low aspect ratio features.

21. The method of claim 1, wherein purging is carried out using a nitrogen purge.

22. The method of claim 1 further comprising the preliminary step of forming at least one primer layer on the substrate before step (a).

23. The method of claim 22, wherein the primer layer is formed by a process selected from anodization, thermal spray, sputtering, vapor deposition and evaporation techniques.

24. The method of claim 22 wherein the primer layer is formed by ALD.

25. The method of claim 1 wherein the mixed coating has a thickness of about 1 to about 250 nanometers.

26. The method of claim 1 wherein the mixed coating has a thickness of about 10 to about 5,000 nanometers.

27. The method of claim 1 wherein the mixed coating has a thickness of about 40 to about 60 nanometers.

28. The method of claim 1 wherein the mixed coating comprises a structure that is amorphous.

29. A plasma resistant coating comprising a monolayer prepared by the method claim 1.

30. The coating of claim 29 having about 1 to about 100 monolayers.

31. The coating of claim 29 having a thickness of about 1 to about 250 manometers.

32. The coating of claim 29 wherein the mixed coating has a thickness of about 10 to about 5,000 manometers.

33. The coating of claim 29 wherein the mixed coating has a thickness of about 40 to about 60 manometers.

34. The coating of claim 29 comprising at least one monolayer that is substantially homogeneous.

35. A component comprising the multi-layer coating of claim 30.

36. The component of claim 35 selected from the group consisting of semiconductor manufacturing equipment, flat panel display manufacturing equipment, a shower head, a chamber wall, a nozzle a plasma generation unit, a diffuser, a gas line interior, and a chamber orifice, chamber liner, and chamber lid.
